(19) United States
(12) Patent Application Publication
(10) Pub. No.: US 2018/0341061 A1
(43) Pub. Date: Nov. 29, 2018

(54) Splitting device and the methods of formation thereof

(71) Applicant: STMicroelectronics (Crolles 2) SAS, Crolles (FR)

(72) Inventors: Jean-Francois Carpentier, Grenoble (FR); Patrick Le Maitre, Biviers (FR)

(21) Appl. No.: 15/607,153

(22) Filed: May 26, 2017

(51) Int. Cl. G02B 6/12; G02B 6/122; G01R 31/308

(52) U.S. Cl. CPC G02B 6/12004; G02B 2006/12154; G01R 31/308; G02B 6/122

(57) ABSTRACT

A power balancing device includes first, second, and third power splitting devices on a semiconductor substrate. The first power splitting device includes an input, a first output, and a second output. A ratio of the power outputs at the first and second outputs is a first ratio. The second power splitting device includes third and fourth outputs and an input coupled to the first output. A ratio of the power outputs at the third and fourth outputs is a second ratio. The third power splitting device includes a fifth and sixth output and an input coupled to the second output. A ratio of the power outputs at the fifth and sixth outputs is a third ratio. The first, second, and third ratios are substantially similar. The input of the first power splitting device and the third and sixth outputs make the input and outputs respectively of the power balancing device.

### TECHNICAL FIELD

The present invention relates generally to a splitting device, and, in particular embodiments, to splitting devices in integrated circuits and variations thereof.

### BACKGROUND

Integrated devices that split an input into one or more outputs are commonly needed in integrated circuits. Reliable behavior of these power splitting devices is necessary to ensure predictable functionality of the integrated circuit. Passive power splitting devices that exhibit various ratios of signal power between the outputs may be fabricated. In some cases, a power splitting device that splits an input signal into one or more output signals of equal power may be required.

### SUMMARY

In accordance with an embodiment of the invention, a power balancing device includes an input, a first output, and a second output. The power balancing device includes a first power splitting device disposed on a semiconductor substrate. The first power splitting device includes an input, a first output, and a second output. A ratio of the power output at the first output of the first power splitting device to the power output at the second output of the first power splitting device is a first ratio.

The power balancing device further includes a second power splitting device. The second power splitting device is also disposed on the semiconductor substrate. The second power splitting device includes an input coupled to the first output of the first power splitting device. The second power splitting device also includes a third output and a fourth output. A ratio of the power output at the third output to the power output at the fourth output is a second ratio.

The power balancing device further includes a third power splitting device. The third power splitting device is also disposed on the semiconductor substrate. The third power splitting device includes an input coupled to the second output of the first power splitting device. The third power splitting device also includes a fifth output and a sixth output. A ratio of the power output at the fifth output to the power output at the sixth output is a third ratio. The first ratio is substantially similar to the second ratio and the third ratio. The input of the power balancing device is the input of the first power splitting device. The first output of the power balancing device is the third output of the second power splitting device. The second output of the power balancing device is the sixth output of the third power splitting device.

In accordance with another embodiment of the invention, a system for device testing includes a semiconductor substrate. The semiconductor substrate includes a first balanced optical power splitter. The first balanced optical power splitter includes an input, a first output, and a second output. The power output of the first output of the first balanced optical power splitter is balanced with the power output of the second output of the first balanced optical power splitter.

The system for device testing further includes a first device under test. The first device under test includes a first input and a first test output. The first input is coupled to the first output of the first balanced optical power splitter. The system for device testing also includes a test probe device. The test probe device includes an optical source photonically coupled to an input of the first balanced optical power splitter. The system for device testing further includes a processor coupled to the first test output. The processor is configured to process the first test output.

In accordance with still another embodiment of the invention, a method of operating a balanced optical power splitter includes providing an optical input signal and splitting the optical input signal into a first split optical signal and a second split optical signal. The signal power of the first split optical signal is substantially different from the signal power of the second split optical signal.

The method of operating a balanced optical power splitter further includes splitting the first split optical signal to generate a first optical output signal. The first optical output signal includes a first signal power. The method of operating a balanced optical power splitter also includes splitting the second split optical signal to generate a second optical output signal. The second optical output signal includes a second signal power. The first signal power is substantially similar to the second signal power.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a functional block diagram of a balanced power splitter in accordance with an embodiment;

FIG. 2 illustrates a functional block diagram of a circuit that receives an input signal and produces a first test output and a second test output using a balanced power splitter in accordance with an embodiment;

FIG. 3 illustrates a functional block diagram of a balanced power splitter implemented with three power splitters in accordance with an embodiment;

FIG. 4 illustrates a schematic layout of a balanced optical power splitter including three optical power splitters in accordance with an embodiment;

FIGS. 5A-5E illustrate several qualitative graphs showing the power of each output of an optical power splitter as a function of input wavelength in accordance with one or more embodiments,

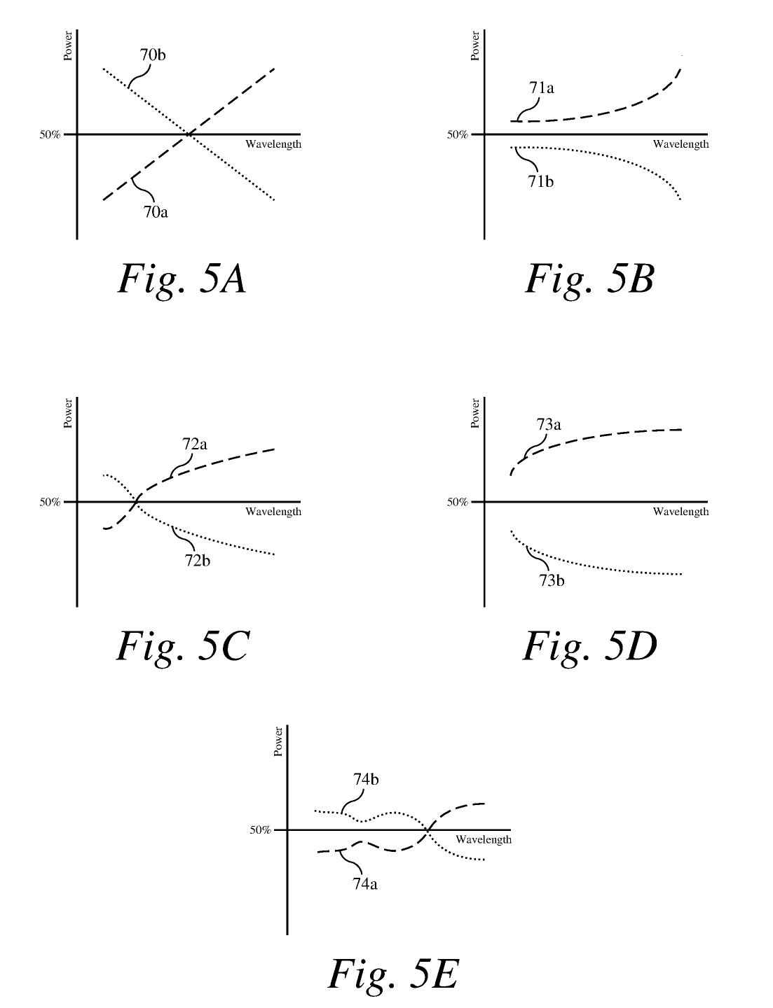

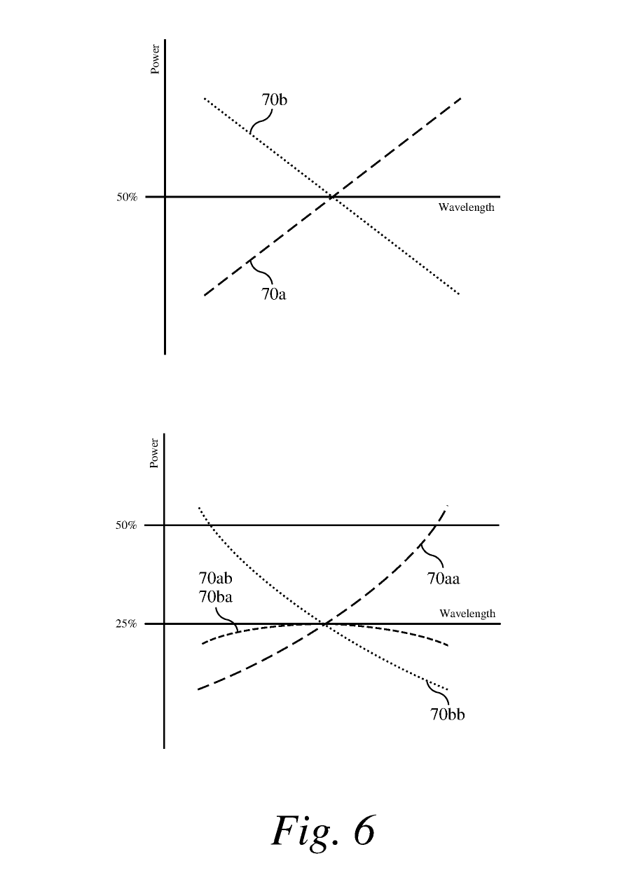

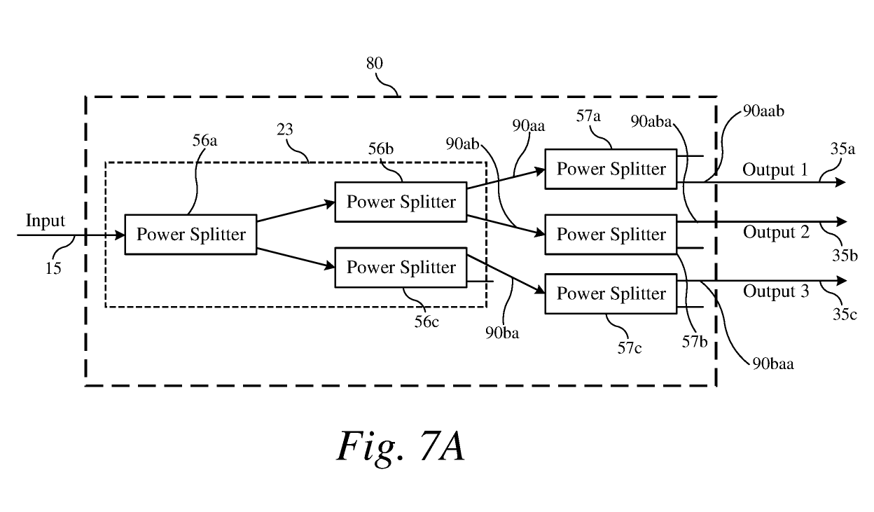

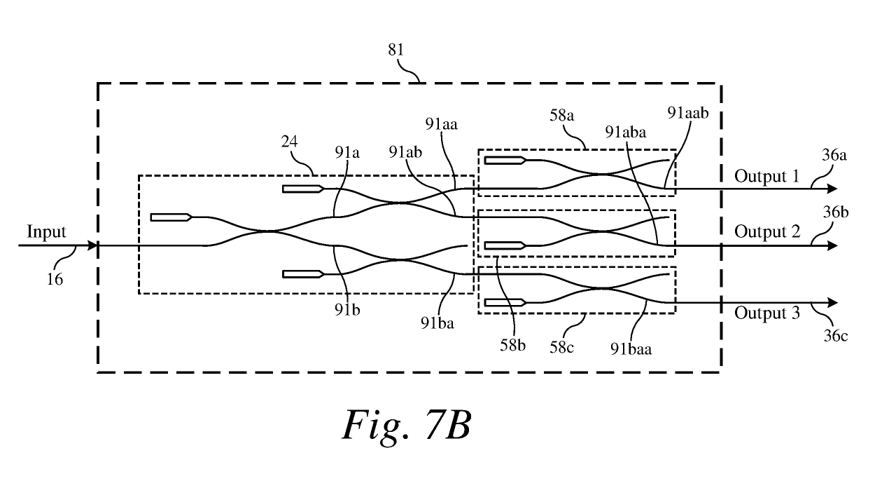

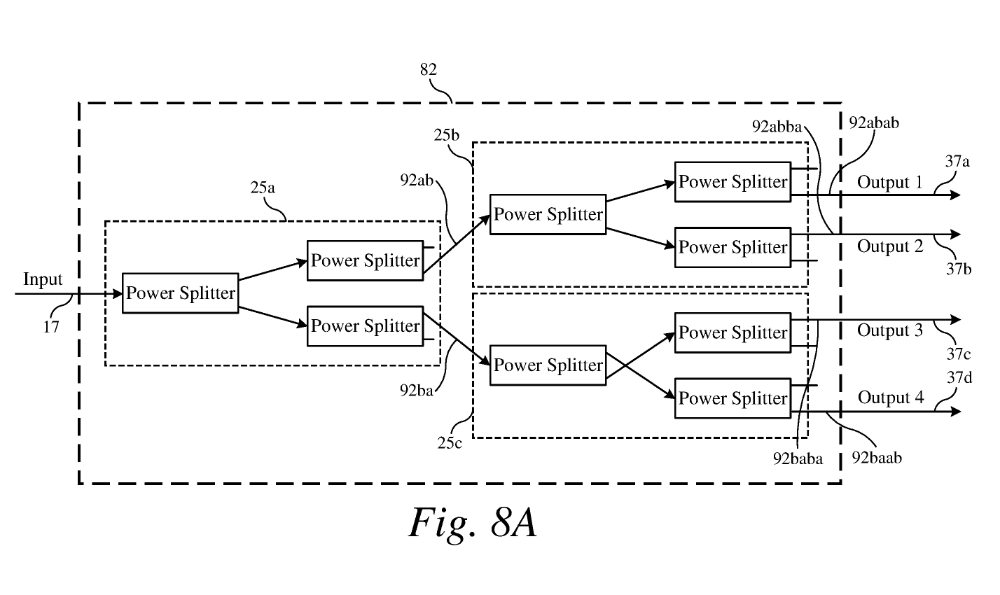

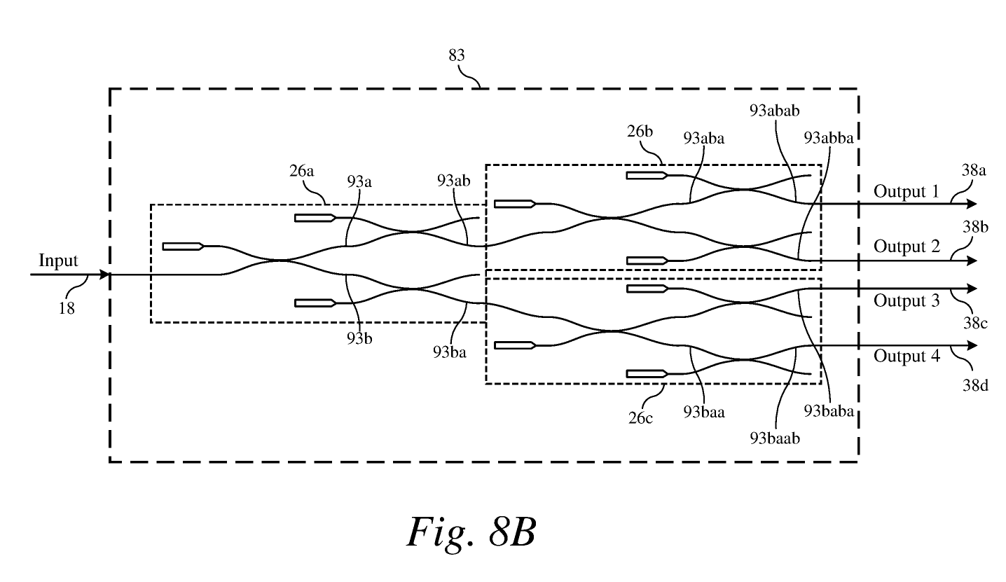

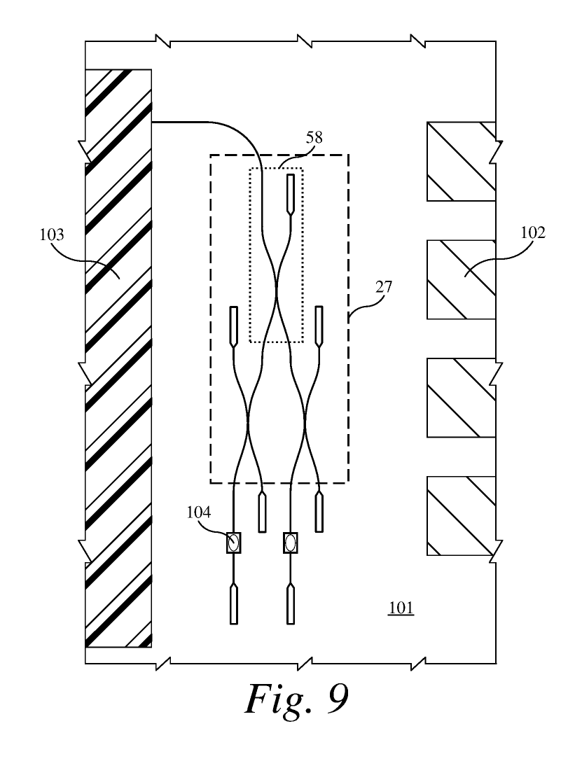

wherein FIG. 5A illustrates an example graph of the power of each output of an optical power splitter as a function of wavelength,

wherein FIG. 5B illustrates another example graph of the power of each output of an optical power splitter as a function of wavelength,

wherein FIG. 5C illustrates still another example graph of the power of each output of an optical power splitter as a function of wavelength,

wherein FIG. 5D illustrates yet another example graph of the power of each output of an optical power splitter as a function of wavelength, and

wherein FIG. 5E illustrates still yet another example graph of the power of each output of an optical power splitter as a function of wavelength;

FIG. 6 illustrates two qualitative graphs showing the power of each output of an optical power splitter as a function of input wavelength, the top graph showing the power output by an optical power splitter and the bottom graph showing the power output by a balanced optical power splitter in accordance with an embodiment;

FIGS. 7A and 7B illustrate a 1×3 balanced power splitter implemented by cascading 1×2 power splitters in accordance with one or more embodiments,

wherein FIG. 7A illustrates a functional block diagram of a 1×3 balanced power splitter implemented by cascading 1×2 power splitters, and

wherein FIG. 7B illustrates a schematic layout of a 1×3 balanced optical power splitter including a 1×2 balanced optical power splitter and three optical power splitters;

FIGS. 8A and 8B illustrate a 1×4 balanced power splitter implemented by cascading 1×2 power splitters in accordance with one or more embodiments,

wherein FIG. 8A illustrates a functional block diagram of a 1×4 balanced power splitter implemented by cascading 1×2 power splitters, and

wherein FIG. 8B illustrates a schematic layout of a 1×4 balanced optical power splitter including three 1×2 balanced optical power splitters; and

FIG. 9 illustrates a partial top view of a substrate including an optical source, a balanced optical power splitter and contact pads in accordance with one or more embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

During integrated circuit fabrication, device parameters may vary within manufacturing tolerances over the surface of a substrate, particularly if the substrate is large. In some cases, these variations may result in differences in the behavior of devices that are sensitive to small fluctuations in the device parameters. For example, the behavior of a splitting device may be influenced by the distance between transmission lines, transmission line width, thickness of material layers, and local stresses on the substrate caused by various layers and features, among others. Due to these variations, it may be difficult to consistently fabricate splitting devices that split an input into outputs of equal power over the entire surface of a large substrate such as a semiconductor wafer.

A specific type of splitting device is a power splitting device. A power splitting device may also be referred to as a power splitter. Power splitting devices receive an input with an initial power and split the input into a plurality of outputs with various percentages of the initial power. Power splitters may accept a variety of inputs. One example input may be a constant electrical input such as a direct current (DC) electrical input. Another example may be a time-modulated electrical input such as an alternating current (AC) signal. Other possible inputs include optical inputs and radio frequency signals, for example. Power may in general refer to electromagnetic power (electric field multiplied by magnetic field) or signal power such as the amplitude of a time-modulated signal, as examples. The following embodiments provide various advantages over conventional power splitting devices.

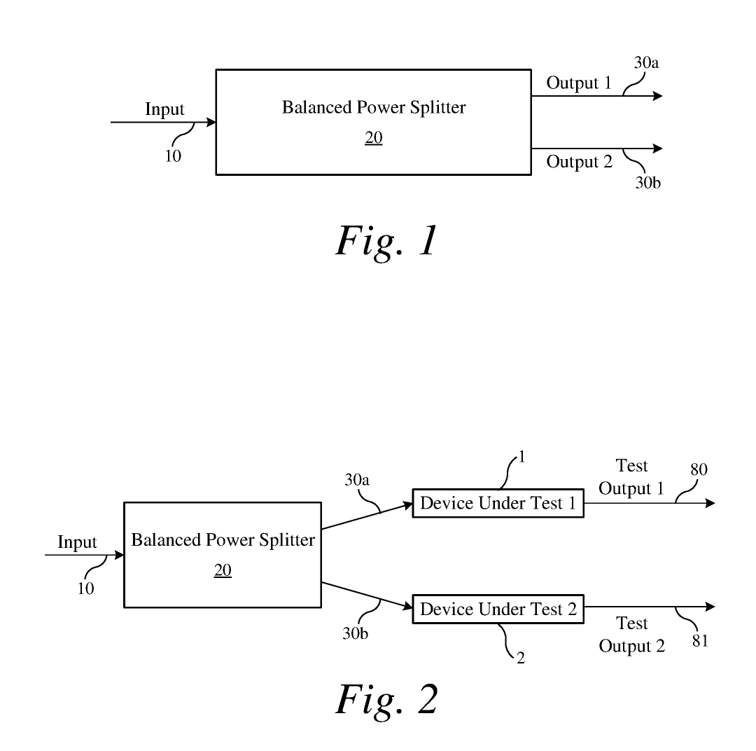

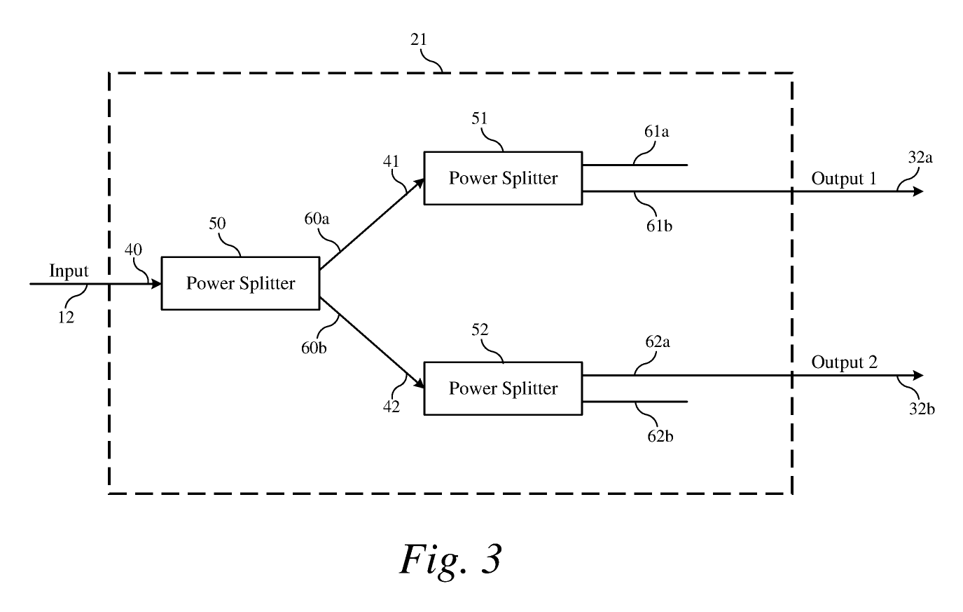

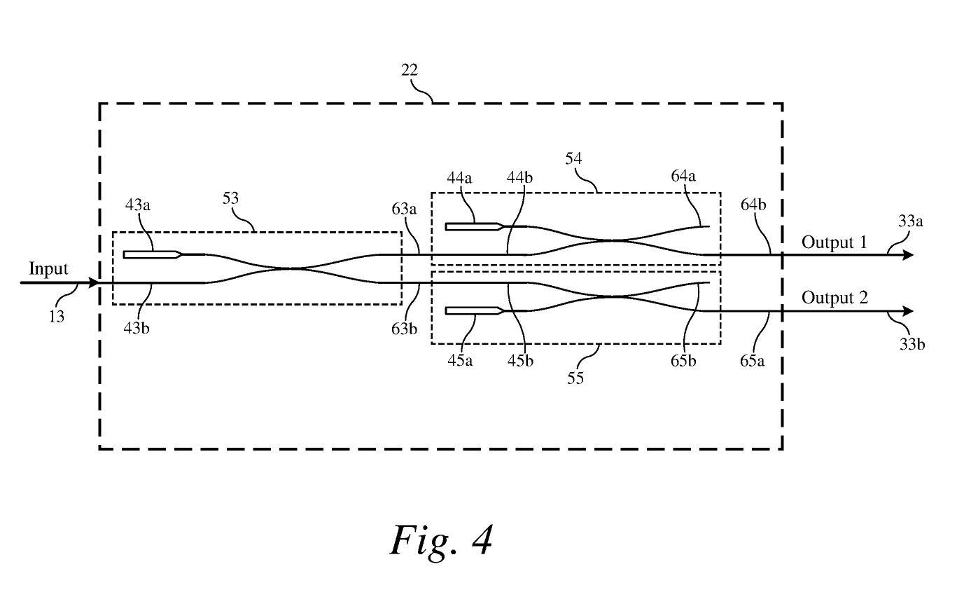

Various embodiments provided below describe various structures of a balanced power splitting device that has advantages over conventional power splitting devices. The following description describes the various embodiments. An embodiment balanced power splitting device (power splitter) will be described using FIG. 1. An embodiment test circuit that uses a balanced power splitter will be described using FIG. 2. Another embodiment balanced power splitter that includes three power splitters will be described using FIG. 3. An embodiment balanced optical power splitter will be described using FIG. 4. FIGS. 5A-5E will be used to describe various possible output power curves as a function of input wavelength of a power splitter. FIG. 6 will be used to describe a comparison between the output power curves of a power splitter and the output power curves of an embodiment balanced power splitter implemented using three power splitters. Two embodiment balanced power splitters with one input signal and three output signals will be described using FIGS. 7A and 7B. Two embodiment balanced power splitters with one input and four outputs will be described using FIGS. 8A and 8B. FIG. 9 will be used to describe an embodiment test circuit on a substrate including a balanced optical power splitter.

FIG. 1 illustrates a functional block diagram of a balanced power splitter in accordance with an embodiment.

Referring to FIG. 1, a balanced power splitter 20 has an input 10, a first output 30a, and a second output 30b. The balanced power splitter 20 is configured to split a signal provided at input 10 into two separate signals with equal power at a first output 30a and a second output 30b respectively. For example, if the power of the signal provided at input 10 is Pᵢ and the power of the output signals at the first output 30a and the second output 30b are Pₐ and P_{b} respectively, then the balanced power splitter 20 is configured to generate the first output 30a and the second output 30b such that Pₐ=P_{b}≤Pᵢ2=Pᵢ−3 dB. A power splitter may also be referred to as a power divider. For an ideal balanced power splitter, 50% of the power Pᵢ of the input signal may be provided at each output. An actual balanced power splitter may experience losses such as intrinsic losses (materials) and radiation losses.

In various embodiments, the balanced power splitter 20 is a passive device. For example, output signals 30a, 30b of equal power may be obtained without adjusting the gain of the output signals 30a, 30b or providing any power to the balanced power splitter 20. Additionally, although the output signals 30a, 30b are of equal power, other aspects of the output signals 30a, 30b may or may not be equivalent. For example, the phase difference between the output signals 30a, 30b may be zero, but a non-zero phase difference between the output signals 30a, 30b is also possible. Similarly, the response of the balanced power splitter 20 may be the same across a range of input frequencies, or may vary depending on the frequency of the input signal.

In one embodiment, the balanced power splitter 20 is a balanced optical power splitter configured to split an optical input signal received at the input 10 into optical output signals. In an alternative embodiment, the balanced power splitter 20 is a balanced electrical power splitter and is configured to split an electrical input signal received at the input 10 into electrical output signals. Additionally, the type of the input signal and the type of the output signals 30a, 30b may be different. When the type of input signal is different from the type of signal of the first output signal 30a or the second output signal 30b, appropriate transduction elements may be included in the balanced power splitter 20.

The balanced power splitter 20 may be referred to as a 1×2 balanced power splitter because it has one input 10 and two outputs 30a, 30b. Similarly, any device having one input and two outputs may be referred to as a 1×2 device. By extension, a power splitter or other device that has one input and three outputs may be referred to as a 1×3 device; a one input, four output device as a 1×4 device and so on.

FIG. 2 illustrates a functional block diagram of a circuit that receives an input signal and produces a first test output 80 and a second test output 81 using a balanced power splitter 20 in accordance with an embodiment.

Referring to FIG. 2, the balanced power splitter 20 is included in a circuit in which the first output 30a is coupled to a first device under test (DUT) 1 and the second output 30b is coupled to a second DUT 2. The first DUT 1 and the second DUT 2 receive the balanced output signals 30a and 30b from the balanced power splitter 20. The first DUT 1 processes the signal from the first output 30a and outputs a signal at a first test output 80. Similarly, the second DUT 2 processes the signal from the second output 30b and outputs a signal at a second test output 81.

The balanced power splitter 20 may serve to provide identical signals to the first DUT 1 and the second DUT 2. For example, in a scenario in which the signal processing of the first DUT 1 and the second DUT 2 are dependent on the power of the input signal 10, the first test output signal 80 and the second test output 81 could be accurately compared if both the first DUT 1 and the second DUT 2 process input signals of equal power.

In various embodiments, the response to a range of input signals may be known for one of the first DUT 1 or the second DUT 2. If the first DUT 1 is the unknown device and the second DUT 2 is the known device then comparison of the signal at the first test output 80 and the signal at the second test output 81 may allow the behavior of the first DUT 1 to be evaluated.

FIG. 3 illustrates a functional block diagram of a balanced power splitter implemented with three power splitters in accordance with an embodiment. The balanced power splitter of FIG. 3 is one example implementation of the balanced power splitter described in reference to FIG. 1.

Referring to FIG. 3, a balanced power splitter 21 includes an input 12, a first output 32a, and a second output 32b. In this embodiment, the balanced power splitter 21 includes a first power splitter 50 that receives the input 12 of the balanced power splitter 21 at an input 40 of the first power splitter 50. The first power splitter 50 splits the signal at the input 40 into two output signals at output 60a and output 60b. Output 60a of the first power splitter 50 is coupled to an input 41 of a second power splitter 51. As with the first power splitter 50, the second power splitter 51 splits the signal received at input 41 from output 60a into two output signals at output 61a and output 61b. Similarly, output 60b of the first power splitter 50 is coupled to an input 42 of a third power splitter 52 that splits the signal received at input 42 from output 60b into two output signals at output 62a and output 62b. The output 61b of the second power splitter 51 is coupled to the first output 32a while the output 62a of the third power splitter 52 is coupled to the second output 32b. In this embodiment, outputs 61a and 62b are not utilized. However, in other embodiments these outputs may be used depending on the application.

The three power splitters may or may not produce output signals with equal power. However, the three power splitters may output similar output signals given the same input signal. For example, the first power splitter 50 may split an input signal with power Pᵢ into a signal with power 0.7Pᵢ at output 60a and a signal with power 0.3Pᵢ at output 60b. The second power splitter 51 and the third power splitter 52 may function in a similar manner to the first power splitter 50. For example, the power of the signals at outputs 61a and 62a may be 0.7 times the power of the signals received at the inputs of the second power splitter 51 and the third power splitter 52 respectively. Similarly, the power of the signals at outputs 61b and 62b may be 0.3 times the power of the signals received at the inputs of second power splitter 51 and the third power splitter 52. Therefore, power splitters in this and following embodiments behave similarly for similar outputs; i.e. ‘a’ outputs in a device behave similarly to other ‘a’ outputs and ‘b’ outputs may behave similarly to other ‘b’ outputs and so on.

Continuing with the above example, the output signal with power 0.7Pᵢ at output 60a becomes the input signal at input 41. Because the ratio of splitting at the outputs of the second power splitter 51 is similar to the first power splitter 50, an output signal with power 0.3(0.7Pᵢ) =0.21Pᵢ is produced at output 61b (and consequently first output 32a). Similarly, the third power splitter 52 receives the output signal with power 0.3Pᵢ from output 60b and produces an output signal with power 0.7(0.3Pᵢ)=0.21Pᵢ at output 62a (second output 32b). Therefore, in this specific example, the output signals at the first output 32a and the second output 32b are equal to 21% of the initial input signal power Pᵢ.

Similarly, an output signal with power 0.7(0.7Pᵢ)=0.49Pᵢ is produced at output 61a and an output signal with power 0.3(0.3Pᵢ)=0.09Pᵢ is produced at output 62b. So in this specific example, the output signal at output 61a is 49% of the initial signal power Pᵢ and the output signal at output 62b is 9% of the initial signal power Pᵢ.

Output signals that are equal or nearly equal in power may be referred to as balanced output signals. Embodiment balanced power splitters split an input signal into balanced output signals. An ideal power splitter may produce balanced output signals. However, process variations and device defects may result in a power splitter that produces output signals with different signal powers. Such a power splitter may be referred to as an unbalanced power splitter. An unbalanced power splitter may produce output signals where the magnitude of a difference between the signal powers at any two outputs is greater than a predetermined threshold. The predetermined threshold may be defined as a deviation of the ratio of the signal power between any two outputs from an ideal ratio of one. The deviation of the ratio of the signal power between two outputs from one may be calculated by subtracting one from the ratio of the signal power between two outputs and taking the absolute value of the result to obtain the magnitude. In this case a power splitter may be considered an unbalanced power splitter if the magnitude of the ratio of the signal power between any two outputs minus one is greater than the predetermined threshold. For example, the predetermined threshold may be 0.2. In the above specific example, for the first power splitter 50, the ratio of the signal power between output 60a and output 60b may be written (0.7Pᵢ)/(0.3Pᵢ)=2.33. Therefore, the magnitude of the ratio of the signal power between output 60a and output 60b minus one is |2.33−1|=1.33. Since 0.33 is greater than 0.2, the first power splitter 50 may be considered an unbalanced power splitter in this specific example. Although the predetermined threshold is described above as being 0.2, in various alternative embodiments, this may be between 0 and 0.2. In further embodiments, the predetermined threshold may be between 0.005 to 0.1.

The above example is described to illustrate the concept of using unbalanced power splitters to produce balanced output signals. This has several possible advantages. For instance, the balance of a power splitter may be affected by a variety of factors. Process variation may cause power splitters on different areas of the wafer to have different output power ratios. However, these variations may be very small or negligible for lengths comparable to the critical dimension of a single die or a single device. So power splitters in close proximity may behave identically.

Power splitters may be further described using a power output ratio. For example, a power splitter may produce an output signal with a signal power that is 0.35Pᵢ (or 35% of the input signal power) at a first output and an output signal that is 0.65Pᵢ (65% of the input signal power) at a second output. The power output ratio of such as power splitter may be written 0.35:0.65. A power splitter with the power output ratio of 0.35:0.65 may be referred to as a 0.35:0.65 power splitter.

Embodiment balanced power splitters may advantageously produce balanced output signals despite processing variation at the wafer level. For example, power splitters at the edge of a wafer may have a power output ratio of 0.35:0.65 and power splitters centrally located on the same wafer may have a power output ratio of 0.52:0.48. A balanced power splitter implemented according to embodiments using 0.35:0.65 power splitters at the edge of the wafer produces a balanced output signal at 22.75% of the input power (e.g. 0.65×0.35=0.2275). In contrast, a balanced power splitter implemented according to embodiments using 0.52:0.48 power splitters centrally located on the wafer produces balanced output signals at 24.96% of the input power (e.g. 0.52×0.48=0.2496). Therefore, embodiment balanced power splitters may have the advantage of being process insensitive to process variations affecting lengths larger than the critical dimension of the balanced power splitter.

Additionally, environmental factors such as temperature, humidity, and external stresses may dynamically affect the ratio of output signal power. These factors may be constant over lengths comparable to the critical dimension of a device, so all constituent power splitters in a balanced power splitter may be affected similarly and a balanced output signal may be advantageously produced regardless of environmental effects.

As previously described above, in one or more embodiments, a power splitter that produces output signals where the magnitude of the ratio of the signal power of any two outputs minus one is less than the predetermined threshold may be considered a balanced power splitter. In a specific example, the signal power at the outputs 60a and 60b of the first power splitter 50 may be 0.46Pᵢ and 0.54Pᵢ respectively where Pᵢ may be the signal power received at input 40 as before. The predetermined threshold may be 0.2 as in the example described previously. The magnitude of the ratio of the signal power between any two outputs minus one may be written as |0.46Pᵢ/0.54Pᵢ−1|=0.15. Therefore, in this specific example, the first power splitter 50 may be considered a balanced power splitter since 0.15 is less than 0.2.

In some implementations, the output signals of embodiment balanced power splitters may not be exactly equal due to process variation, environmental factors, or unequal response across a parameter of the input signal (such as frequency or amplitude of the signal). In this case, the magnitude of the ratio of the signal powers of any two outputs minus one may be less than the predetermined threshold as previously described.

The outputs of a power splitter may be considered complementary. For example, the power of the input signal to the power splitter is equal to the sum of the power of all of the output signals of the power splitter. Complementary outputs of power splitters may allow for the implementation of a balanced power splitter using only unbalanced power splitters.

It should be noted that in the above examples, it is assumed that the power splitter is an ideal power splitter and does not experience losses within the device. However, in practical application, losses may occur such that the sum of the power of all output signals of a power splitter is less than the power of the input signal. For example, in a 1×2 power splitter, Pₐ+P_{b} =Pᵢ*L where Pₐ is the signal power at a first output of the 1×2 power splitter, P_{b} is the signal power at a second output of the 1×2 power splitter, and Pᵢ is the signal power at an input of the 1×2 power splitter, and L is the loss of the power splitter (L in linear, for example 0.2 dB gives L˜0.955). The outputs of a power splitter may still be considered complementary in the case of nonzero losses because of this relationship.

Balanced power splitters described in previous embodiments as well as future embodiments may still produce balanced output signals even when there is power loss associated with the device. For example, taking the above scenario in which Pₐ=0.7Pᵢ and P_{b}=0.3Pᵢ nonzero losses result in Pₐ=0.7*(Pᵢ*L) and P_{b}=0.3*(Pᵢ*L). A balanced power splitter 20 implemented with these power splitters may still produce balanced output signals. The signal power at output 61b (32a) may be written

0.3*[0.7*(Pi*L)*L]=0.21*Pi*L²

whereas the signal power at output 62a (32b) may be written

0.7*[0.3*(P_{i*L})*L]=0.21*Pi*L².

Therefore, the signal power at the outputs 32a and 32b may be balanced as defined by a predetermined threshold as previously described.

Integrated optical devices for directly processing optical signals are important in many applications involving optical fiber communications. Optical fiber communications are increasingly replacing wired electronic communications due to various advantages such as increased throughput, increased bandwidth, and immunity to electromagnetic interference. Integrated optical circuits commonly incorporate a variety of optical devices including optical power splitters. Coupling coefficients are sensitive to process variations since they are related to propagation constants of guided modes which are sensitive to waveguide dimensions. For this reason, a balanced optical power splitter implemented using unbalanced optical power splitters may be advantageous to allow for lower tolerances during fabrication while still producing balanced optical power splitters over the entire surface of a substrate.

FIG. 4 illustrates a schematic layout of a balanced optical power splitter including three optical power splitters in accordance with an embodiment. The balanced optical power splitter of FIG. 4 is one example implementation of the balanced power splitter described in reference to FIG. 3.

Referring to FIG. 4, a balanced optical power splitter 22 includes an input 13, a first output 33a, and a second output 33b. The balanced optical power splitter 22 includes a first optical power splitter 53. In one embodiment, the first optical power splitter 53 is a directional coupler utilizing only one input. In some cases, a directional coupler may also be referred to as an evanescent coupler. The directional coupler may include two waveguides that are close enough together to allow for overlapping modes between the two waveguides. The region of the waveguides where modes overlap may be considered an interaction region. In the interaction region, signal power may be transferred between the two waveguides. The distance between waveguides in the interaction region may be about 100 nm, but may vary depending on fabrication techniques and the wavelength of the input signals. In other embodiments, the first optical power splitter 53 may be a ‘Y’ junction or a multimode interference (MMI) device.

The first optical power splitter 53 includes a first input 43a, a second input 43b, a first output 63a, and a second output 63b. In one embodiment, the input 43a is unused and is terminated so as to not influence input 43b, output 63a, or output 63b. Input 43b is coupled to input 13. Alternatively, input 43b, may be unused while input 43a is coupled to input 13. The first optical power splitter 53 splits the optical signal received from input 13 into two optical output signals at output 63a and output 63b. Output 63a is coupled to input 44b of a second optical power splitter 54. Output 63b is coupled to input 45b of a third optical power splitter 55. Input 44a and input 45a are unused and terminated similar to input 43a of the first optical power splitter 53. Output 64b of the second optical power splitter 54 is coupled to output 33a while output 65a of the third optical power splitter 55 is coupled to output 33b. Output 64a and output 65b of the second and third optical power splitters respectively may be unused. In some cases, output 64a and output 65b may be terminated similar to input 43a. Alternatively, output 64a and/or output 65b may be used as additional outputs of the balanced optical power splitter 22 depending on application.

The three optical power splitters may or may not output signals of equal power, but behave similarly to one another as previously described in reference to FIG. 2; i.e. ‘a’ outputs behave similar to other ‘a’ outputs and so on. Further, the ‘a’ outputs such as outputs 63a, 64a, and 65a may be referred to as the coupled output of the optical power splitter. The ‘b’ outputs such as outputs 63b, 64b, and 65b may be referred to as transmitted outputs. The terminated unused inputs such as inputs 43a, 44a, and 45a may be referred to as isolated inputs.

The path of the signal from input 13 to output 33a may be referred to as ‘ab’ because it goes through output 63a and then output 64b. Similarly, the path of the signal from input 13 to output 33b may be referred to as ‘ba’. At each split, a percentage of the input signal power is transmitted to an ‘a’ output and a percentage is transmitted to a ‘b’ output. As in the example described previously in reference to FIG. 2, unbalanced optical power splitters may be combined as described in FIG. 3 and produce balanced optical output signals.

The balanced optical power splitter 21 of FIG. 3 may have similar advantages as those discussed above in reference to FIG. 2. Additionally, a constituent optical power splitter may have a different ratio of output power depending on the wavelength of the input signal. For example, if the power of the signal at input 13 is Pᵢ, the power of the signal at output 63a may be 0.47Pᵢ for an input signal at a first wavelength (e.g. λ=1290 nm), 0.5Pᵢ for an input signal at a second wavelength (e.g. λ=1300 nm), and 0.62Pᵢ for an input signal at a third wavelength (e.g. λ=1330 nm). In this example, the output of the constituent optical power splitter may be balanced in a small window around the third wavelength (e.g. a small window around λ=1330 nm).

A potentially desirable attribute of a balanced optical power splitter may be flat response across a band of wavelengths. For example, balanced optical power splitters in a system designed to operate in the O-band may need to have a flat response across at least the majority of the range from about λ=1260 nm to about λ=1360 nm. Other possible bands are the E-band (1360 nm to 1460 nm), S-band (1460 nm to 1530 nm), C-band (1530 nm to 1565 nm), L-band (1565 nm to 1625 nm), and the U-band (1625 nm to 1675 nm). In many cases, different wavelength response in optical devices is determined by processing variations at the wafer level that are negligible or relatively minor at the device level. Balanced optical power splitters composed of three optical power splitters in close proximity on the substrate may have the same or nearly the same response for all wavelengths. For reasons described in previous examples, such a balanced optical power splitter may advantageously produce balanced output signals across all wavelengths or a band of wavelengths.

Referring back to the balanced optical power splitter 22 shown in FIG. 4, the first optical power splitter 53, second optical power splitter 54, and third optical power splitter 55 may produce any power output curve as a function of wavelength. In cases where the power output curves of the three optical power splitters is sufficiently similar, the balanced optical power splitter 22 may produce balanced output signals. In one embodiment, the balanced optical power splitter 22 produces a flat response for input signal wavelengths ranging between about λ=1290 nm and about λ=1330 nm. Other embodiments may produce a flat response over other wavelength ranges. More details and examples of power output curves as a function of input wavelength will be described in subsequent paragraphs.

FIGS. 5A-5E illustrate several qualitative graphs showing the power of each output of an optical power splitter as a function of input wavelength in accordance with one or more embodiments, where FIG. 5A illustrates an example graph of the power of each output of an optical power splitter as a function of wavelength, FIG. 5B illustrates another example graph of the power of each output of an optical power splitter as a function of wavelength, FIG. 5C illustrates still another example graph of the power of each output of an optical power splitter as a function of wavelength, FIG. 5D illustrates yet another example graph of the power of each output of an optical power splitter as a function of wavelength, and FIG. 5E illustrates still yet another example graph of the power of each output of an optical power splitter as a function of wavelength.

The balanced optical power splitters of previous embodiments may be implemented using optical power splitters with an output power ratio that depends on the wavelength of the input signal. Several example qualitative output curves are presented in the following to illustrate possible optical power splitters that may be used to implement a balanced optical power splitter. These are merely qualitative examples to aid in understanding of the embodiments and are in no way limiting. Other suitable output curves may be apparent to one of ordinary skill in the art.

Referring to FIG. 5A, a qualitative graph of the signal power for each output of an optical power splitter as a function of wavelength is shown as a possible example of operation over a wavelength range. The output signal power is shown as a percentage of the input signal power. The optical power splitter produces a first power output 70a and a second power output 10b corresponding to an ‘a’ output and a ‘b’ output respectively. The ‘a’ and ‘b’ outputs are as described in previous embodiments. As previously described, the ‘a’ and ‘b’ outputs are complementary. In this embodiment, the power output has a linear response over the given wavelength range. At a wavelength in approximately the middle of the range, the first power output 70a and the second power output 70b are both 50% of the input signal power. At this wavelength, the optical power splitter produces balanced output signals.

A balanced optical power splitter may be implemented using optical power splitters with an output power response similar to that shown in FIG. 5A in accordance with previously described embodiments. A possible advantage of this balanced power splitter is that it may have a flat response over a full range of wavelengths even though constituent optical power splitters are only balanced for a small subset of the wavelength range.

Referring to FIG. 5B, another qualitative graph of the signal power for a first power output 71a and a second power output 71b of an optical power splitter as a function of wavelength is shown as a possible example of operation over a wavelength range. In this embodiment, the power output has an exponential response over the wavelength range. The first power output 71a and the second power output 71b do not cross at 50% of the input signal power, so the optical power splitter does not produce balanced output signals at any wavelength in the given range. However, a balanced optical power splitter implemented using optical power splitters with an output power response similar to that shown in FIG. 5B in accordance with previously described embodiments may still produce a flat response over the given wavelength range for reasons previously described.

Referring to FIG. 5C, still another qualitative graph of the signal power for a first power output 72a and a second power output 72b of an optical power splitter is illustrated. The power output of this example optical power splitter is irregular over the given wavelength range. In this embodiment, the first power output 72a and the second power output 72b cross at 50% power near the lower end of the range. A balanced optical power splitter implemented using optical power splitters with the response shown in FIG. 5C may still produce a flat response over the given wavelength range for reasons previously described.

Referring to FIG. 5D, yet another qualitative graph of the signal power for a first power output 73a and a second power output 73b of an optical power splitter is illustrated. The power output of this example optical power splitter approaches a flat response in the upper end of the wavelength range. However, the approximate flat response is not a balanced power output as the first power output 73a is above 50% of the input signal power while the second power output 73b is below 50% of the input signal power. A balanced optical power splitter implemented using optical power splitters with the response shown in FIG. 5D may still produce a flat response over the given wavelength range for reasons previously described.

Referring to FIG. 5E, yet another qualitative graph of the signal power for a first power output 74a and a second power output 74b of an optical power splitter is illustrated. The power output of this example optical power splitter is irregular over the given wavelength range such that it could not easily be described as a function of the wavelength. The first power output 74a and the second power output 74b are still complementary over the wavelength range, so a balanced optical power splitter implemented using optical power splitters with the response shown in FIG. 5E may still produce a flat response over the given wavelength range for reasons previously described.

FIG. 6 illustrates two qualitative graphs showing the power of each output of an optical power splitter as a function of input wavelength, the top graph showing the power output by an optical power splitter and the bottom graph showing the power output by a balanced optical power splitter in accordance with an embodiment.

Referring to FIG. 6, the top graph illustrates a first power output 70a and a second power output 70b from an optical power splitter and is similar to the graph shown in FIG. 5A. The bottom graph is a qualitative graph of the signal power for each output of a balanced optical power splitter implemented using three optical power splitters with output power responses similar to the top graph in accordance with previously described embodiments. The balanced optical power splitter produces a first power output 70aa, second power output 70ab, third power output 70ba, and fourth power output 70bb. The four outputs correspond to the ‘aa’, ‘ab’, ‘ba’, and ‘bb’ output paths as previously described in reference to FIG. 4.

The constituent optical power splitters have similar responses over the wavelength range, so the second power output 70ab and the third power output 70ba are identical. As a result, the balanced optical power splitter produces a balanced output signal over the wavelength range. In various embodiments, the constituent optical power splitters of a balanced optical power splitter may produce approximately balanced output signals over a wavelength range. In this case, the deviation from a constant power response may be small. For example, the difference between the second power output 70b and the first power output 70a may be 1% at the bottom end of the wavelength range in the top graph of FIG. 6. In this case, the maximum deviation of the second power output 70ab and the third power output 70ba is about 0.01%. Put another way, the power output of 70ab and 70ba would be 24.99% of the input signal power at the endpoints and 25% of the input signal power at the center of the wavelength range.

FIGS. 7A and 7B illustrate a 1×3 balanced power splitter implemented by cascading 1×2 power splitters in accordance with one or more embodiments, where FIG. 7A illustrates a functional block diagram of a 1×3 balanced power splitter implemented by cascading 1×2 power splitters and FIG. 7B illustrates a schematic layout of a 1×3 balanced optical power splitter including a 1×2 balanced optical power splitter and three optical power splitters.

Referring to FIG. 7A, a 1×3 balanced power splitter 80 has an input 15, first output 35a, second output 35b, and a third output 35c. The 1×3 balanced power splitter 80 includes a 1×2 balanced power splitter 23 that receives the input 15. The 1×2 power splitter 23 includes three power splitters 56a, 56b, and 56c and may be as in previously described embodiments such as in reference to FIG. 3, for example. The 1×3 balanced power splitter 80 also includes a three more power splitters 57a, 57b, and 57c. The power splitters 56a, 56b, 56c, 57a, 57b, and 57c may have similar output power ratios.

Output 90aa, output 90ab, and output 90ba are coupled to the inputs of power splitters 57a, 57b, and 57c respectively. The ‘b’ output of power splitter 57a is output 90aab and is coupled to the first output 35a of the 1×3 balanced power splitter 80. Similarly, the ‘a’ outputs of power splitters 57b and 57c are outputs 90aba and outputs 90baa and are coupled to the second output 35b and the third output 35c of the 1×3 balance power splitter 80 respectively. As with previous embodiments, the labeling notation of the internal outputs for the balanced power splitter reflects the path of the input signal. For example, the output 90aab is the ‘aab’ path sequentially through power splitters 56a, 56b, and 57a.

It should be noted that the 1×3 balanced power splitter 80 is an example of an application of a 1×2 balanced power splitter of previous embodiments in which the ‘aa’ output is utilized. The arrangement of power splitters in the 1×3 balanced power splitter 80 produces three balanced output signals that follow a path containing two ‘a’ outputs and a ‘b’ output: ‘aab’, ‘aba’, and ‘baa’. An alternative implementation may use paths with two ‘b’ outputs and an ‘a’ output. In this way, power splitters may be cascaded to produce 1×n balanced power splitters.

Referring to FIG. 7B, a 1×3 balanced optical power splitter 81 includes an input 16, first output 36a, second output 36b, third output 36c. The 1×3 balanced optical power splitter 81 is a possible optical implementation of the 1×3 balanced power splitter 80 of FIG. 7A. Similar to 1×3 balanced power splitter 80, 36a, 36b, and 36c follow a path containing two ‘a’ outputs and a ‘b’ output through constituent balanced optical power splitter 24 and optical power splitters 58a, 58b, and 58c. For example, the input signal is split along the path 91b→91ba→91baa for third output 36c.

FIGS. 8A and 8B illustrate a 1×4 balanced power splitter implemented by cascading 1×2 power splitters in accordance with one or more embodiments, where FIG. 8A illustrates a functional block diagram of a 1×4 balanced power splitter implemented by cascading 1×2 power splitters and FIG. 8B illustrates a schematic layout of a 1×4 balanced optical power splitter including three 1×2 balanced optical power splitters.

Referring to FIG. 8A, a 1×4 balanced power splitter 82 includes three balanced power splitters 25a, 25b, and 25c cascaded to split an input 17 into a four balanced outputs signals at a first output 37a, second output 37b, third output 37c, and fourth output 37d. The 1×4 balanced power splitter 82 produces balanced output signals following a path containing two ‘a’ outputs and two ‘b’ outputs from constituent power splitters included in balanced power splitters 25a, 25b, and 25c. Output 92ab and output 92ba are coupled to inputs of balanced power splitter 25b and balanced power splitter 25c respectively. Output 92abab, output 92abba, output 92baba, and output 92baab are coupled to first output 37a, second output 37b, third output 37c, and fourth output 37d respectively.

Referring to FIG. 8B, a 1×4 balanced optical power splitter 83 includes an input 18, first output 37a, second output 37b, third output 37c, and fourth output 37d. The 1×4 balanced optical power splitter 83 is a possible implementation of the 1×4 balanced power splitter 82 of FIG. 8A. Similar to the 1×4 balanced optical power splitter 82, the outputs 37a, 37b, 37c, and 37d follow a path containing two ‘a’ outputs and two ‘b’ outputs through constituent balanced optical power splitters 26a, 26b, and 26c. For example, the input signal is split along the path 93a→93ab→93aba→93abab for second output 38b.

FIG. 9 illustrates a partial top view of a substrate including an optical source, a balanced optical power splitter and contact pads in accordance with an embodiment.

Referring to FIG. 9, a substrate 101 includes an optical source 103, a balanced optical power splitter 27, and contact pads 102. The substrate 101 may a semiconductor substrate in various embodiments. In one embodiment, the substrate 101 is a silicon wafer. The substrate 101 may include electronic and/or photonic circuitry. In one embodiment, the substrate 101 includes integrated photonic circuitry that may be considered a photonic integrated circuit (IC). The contact pads 102 may be used to make electrical contact with one or more devices under test (DUTs) included in the substrate 101.

The optical source 103 may be an external source that is aligned with a vertical coupler for testing of devices on the substrate 101. In this configuration, the optical source 103 may be considered photonically coupled to the vertical coupler. The optical source 103 may be part of a test probe device. The test probe device may also include a processor to process signals received from devices on substrate 101.

The balanced optical power splitter 27 includes optical power splitters 58 and may be as described in previous embodiments. In one embodiment, the optical power splitter 27 comprises a silicon waveguide disposed on a silica (SiO₂) substrate. The silica may be implemented by using a silicon-on-insulator (SOI) wafer. Additional balanced optical power splitters may also be included on the substrate 101.

The devices under test (DUTs) may be optical and/or electrical circuits that process an optical or electrical input signal and output a test signal. The DUTs may be configured on the substrate 101 in an arrangement similar to the circuit described previously in reference to FIG. 2, for example. The balanced optical outputs of the balanced optical power splitter 27 are transduced into electrical output signals by photodiodes 104. In other embodiments, the balanced optical output signals may be fed directly into test circuits rather than being converted into electrical signals. Additionally, other methods of signal transduction may be used as well as incorporation of additional intervening circuitry between the optical source 103 and the balanced optical power splitter 27 or between the balanced optical power splitter 27 and the contact pads and DUTs on the substrate 101.

Additional electronic circuitry may include components such as diodes, thyristors, transistors, transmission lines, ground planes, redistribution layers (RDLs), and insulating regions. Additional optical circuitry may include ring resonators, Bragg gratings, and waveguides. One or more of the balanced optical power splitter 27, the contact pads 103, and the photodiodes 104 may be in a kerf region or scribing area and consequently be removed during a dicing procedure of the substrate 101. Alternatively, the one or more of the balanced optical power splitter 27, contact pads 103, and the photodiodes 104 may be included in the final device to enable fine tuning of device parameters and/or debugging of the final device.

Example embodiments of the invention are summarized here. Other embodiments can be understood from the entirety of the specification and claims filed herein.

### EXAMPLE 1

A power balancing device includes an input, a first output, and a second output, the power balancing device including: a first power splitting device disposed on a semiconductor substrate and including an input and a first output and a second output, where a ratio of the power output at the first output of the first power splitting device to the power output at the second output of the first power splitting device is a first ratio; a second power splitting device disposed on the semiconductor substrate and including an input coupled to the first output of the first power splitting device, the second power splitting device including a third output and a fourth output, where a ratio of the power output at the third output to the power output at the fourth output is a second ratio; and a third power splitting device disposed on the semiconductor substrate and including an input coupled to the second output of the first power splitting device, the third power splitting device including a fifth output and a sixth output, where a ratio of the power output at the fifth output to the power output at the sixth output is a third ratio, and where the first ratio is substantially similar to the second ratio and the third ratio, where the input of the power balancing device is the input of the first power splitting device, and where the first output of the power balancing device is the third output and the second output of the power balancing device is the sixth output.

### EXAMPLE 2

The device of example 1, where the power balancing device is configured to receive a range of wavelengths at the input, and where a ratio of the power output at the first output of the power balancing device to the power output at the second output of the power balancing device is substantially the same for all wavelengths in the range of wavelengths.

### EXAMPLE 3

The device of example 2, where the range of wavelengths is between 1290 nm and 1330 nm.

### EXAMPLE 4

The device of one of examples 1 to 3, where the power balancing device is configured to receive a range of wavelengths at the input, and where, for the range of wavelengths received at the input of the power balancing device, the power output of the first output of the power balancing device is balanced with the power output of the second output of the power balancing device.

### EXAMPLE 5

The device of one of examples 1 to 4, where an absolute value of a deviation between the first output of the power balancing device and the second output of the power balancing device is less than a predetermined threshold, and where the deviation is a difference between a ratio of the power output at the first output of the power balancing device to the power output at the second output of the power balancing device and one.

### EXAMPLE 6

The device of example 5, where the predetermined threshold is between 0.005 and 0.1.

### EXAMPLE 7

The device of one of examples 5 and 6, where, for each of the first ratio, the second ratio, and the third ratio, an absolute value of a difference between the respective ratio and one is greater than the predetermined threshold.

### EXAMPLE 8

The device of one of examples 1 to 7, where each of the first power splitting device, the second power splitting device, and the third power splitting device is an optical directional coupler.

### EXAMPLE 9

The device of one of examples 1 to 8, further including: a first additional device including an input coupled to the first output of the second power splitting device. The first additional device includes a first additional output. The first additional device includes a second additional output. The device includes a second additional device including an input coupled to the first output of the third power splitting device. The second additional device includes a third additional output. The second additional device includes a fourth additional output. Any two of the first additional output, the second additional output, the third additional output, and the fourth additional output are balanced.

### EXAMPLE 10

A system for device testing including: a semiconductor substrate including a first balanced optical power splitter including an input, a first output, and a second output, where the power output of the first output of the first balanced optical power splitter is balanced with the power output of the second output of the first balanced optical power splitter. The system for device testing includes a first device under test including a first input and a first test output, the first input coupled to the first output of the first balanced optical power splitter. The system for device testing includes a test probe device including an optical source photonically coupled to an input of the first balanced optical power splitter. The test probe device includes a processor coupled to the first test output, the processor being configured to process the first test output.

### EXAMPLE 11

The system of example 10, where the first balanced optical power splitter includes: a first power splitting device disposed on a semiconductor substrate and including an input and a first output and a second output, where a ratio of the power output at the first output of the first power splitting device to the power output at the second output of the first power splitting device is a first ratio; a second power splitting device disposed on the semiconductor substrate and including an input coupled to the first output of the first power splitting device, the second power splitting device including a third output and a fourth output, where a ratio of the power output at the third output to the power output at the fourth output is a second ratio; and a third power splitting device disposed on the semiconductor substrate and including an input coupled to the second output of the first power splitting device, the third power splitting device including a fifth output and a sixth output, where a ratio of the power output at the fifth output to the power output at the sixth output is a third ratio, and where the first ratio is substantially similar to the second ratio and the third ratio, where the input of the first balanced optical power splitter is the input of the first power splitting device, where the first output of the first balanced optical power splitter is the third output and the second output of the first balanced optical power splitter is the sixth output.

### EXAMPLE 12

The system of one of examples 10 and 11, where the first balanced optical power splitter is configured to receive a range of wavelengths at the input, and where, for the range of wavelengths received at the input of the first balanced optical power splitter, the power output of the first output of the first balanced optical power splitter is balanced with the power output of the second output of the first balanced optical power splitter.

### EXAMPLE 13

The system of one of examples 10 to 12, where the first balanced optical power splitter is disposed at a central region of the semiconductor substrate, and the semiconductor substrate further includes a second balanced optical power splitter disposed at an edge region of the semiconductor substrate, the second balanced optical power splitter including an input, a first output, and a second output, where the power output of the first output of the second balanced optical power splitter is balanced with the power output of the second output of the second balanced optical power splitter.

### EXAMPLE 14

The system of one of examples 10 to 13, where the semiconductor substrate further includes a second device under test including a second input and a second test output, the second input coupled to the second output of the first balanced optical power splitter, where the processor is further configured to process the second test output.

### EXAMPLE 15

The system of one of examples 10 to 14, where the semiconductor substrate is a silicon wafer.

### EXAMPLE 16

A method of operating a balanced optical power splitter including: providing an optical input signal; and splitting the optical input signal into a first split optical signal and a second split optical signal, where the signal power of the first split optical signal is substantially different from the signal power of the second split optical signal; splitting the first split optical signal to generate a first optical output signal including a first signal power; and splitting the second split optical signal to generate a second optical output signal including a second signal power, where the first signal power is substantially similar to the second signal power.

### EXAMPLE 17

The method of example 16, where the optical input signal includes a wavelength within a range of wavelengths, and where the first signal power is substantially similar to the second signal power for all wavelengths in the range of wavelengths.

### EXAMPLE 18

The method of example 17, where the range of wavelengths is between 1290 nm and 1330 nm.

### EXAMPLE 19

The method of one of examples 16 to 18, where an absolute value of a deviation between the first signal power and the second signal power is less than a predetermined threshold, and where the deviation is a difference between a ratio of the first signal power to the second signal power and one.

### EXAMPLE 20

The method of example 19, where an absolute value of a deviation between the first split optical signal and the second split optical signal is greater than the predetermined threshold, and where the deviation is a difference between a ratio of the signal power of the first split optical signal to the signal power of the second split optical signal and one.

While this invention has been described with reference to illustrative embodiments, this description is not intended to be construed in a limiting sense. Various modifications and combinations of the illustrative embodiments, as well as other embodiments, will be apparent to persons skilled in the art upon reference to the description. It is therefore intended that the appended claims encompass any such modifications or embodiments.

What is claimed is:

1. A power balancing device comprising an input, a first output, and a second output, the power balancing device comprising:
a first power splitting device disposed on a semiconductor substrate and comprising an input and a first output and a second output, wherein a ratio of the power output at the first output of the first power splitting device to the power output at the second output of the first power splitting device is a first ratio;
a second power splitting device disposed on the semiconductor substrate and comprising an input coupled to the first output of the first power splitting device, the second power splitting device comprising a third output and a fourth output, wherein a ratio of the power output at the third output to the power output at the fourth output is a second ratio; and
a third power splitting device disposed on the semiconductor substrate and comprising an input coupled to the second output of the first power splitting device, the third power splitting device comprising a fifth output and a sixth output, wherein a ratio of the power output at the fifth output to the power output at the sixth output is a third ratio, and wherein the first ratio is substantially similar to the second ratio and the third ratio, wherein the input of the power balancing device is the input of the first power splitting device, and wherein the first output of the power balancing device is the third output and the second output of the power balancing device is the sixth output.

2. The device of claim 1, wherein the power balancing device is configured to receive a range of wavelengths at the input, and wherein a ratio of the power output at the first output of the power balancing device to the power output at the second output of the power balancing device is substantially the same for all wavelengths in the range of wavelengths.

3. The device of claim 2, wherein the range of wavelengths is between 1290 nm and 1330 nm.

4. The device of claim 1, wherein the power balancing device is configured to receive a range of wavelengths at the input, and wherein, for the range of wavelengths received at the input of the power balancing device, the power output of the first output of the power balancing device is balanced with the power output of the second output of the power balancing device.

5. The device of claim 1, wherein an absolute value of a deviation between the first output of the power balancing device and the second output of the power balancing device is less than a predetermined threshold, and wherein the deviation is a difference between a ratio of the power output at the first output of the power balancing device to the power output at the second output of the power balancing device and one.

6. The device of claim 5, wherein the predetermined threshold is between 0.005 and 0.1.

7. The device of claim 5, wherein, for each of the first ratio, the second ratio, and the third ratio, an absolute value of a difference between the respective ratio and one is greater than the predetermined threshold.

8. The device of claim 1, wherein each of the first power splitting device, the second power splitting device, and the third power splitting device is an optical directional coupler.

9. The device of claim 1, further comprising:
a first additional device comprising:
an input coupled to the first output of the second power splitting device,
a first additional output, and
a second additional output; and
a second additional device comprising:
an input coupled to the first output of the third power splitting device,
a third additional output, and
a fourth additional output, wherein any two of the first additional output, the second additional output, the third additional output, and the fourth additional output are balanced.

10. A system for device testing comprising:
a semiconductor substrate comprising:
a first balanced optical power splitter comprising an input, a first output, and a second output, wherein the power output of the first output of the first balanced optical power splitter is balanced with the power output of the second output of the first balanced optical power splitter, and
a first device under test comprising a first input and a first test output, the first input coupled to the first output of the first balanced optical power splitter; and
a test probe device comprising:
an optical source photonically coupled to an input of the first balanced optical power splitter, and
a processor coupled to the first test output, the processor being configured to process the first test output.

11. The system of claim 10, wherein the first balanced optical power splitter comprises:
a first power splitting device disposed on the semiconductor substrate and comprising an input, a first output, and a second output, wherein a ratio of the power output at the first output of the first power splitting device to the power output at the second output of the first power splitting device is a first ratio;
a second power splitting device disposed on the semiconductor substrate and comprising an input coupled to the first output of the first power splitting device, the second power splitting device comprising a third output and a fourth output, wherein a ratio of the power output at the third output to the power output at the fourth output is a second ratio; and
a third power splitting device disposed on the semiconductor substrate and comprising an input coupled to the second output of the first power splitting device, the third power splitting device comprising a fifth output and a sixth output, wherein a ratio of the power output at the fifth output to the power output at the sixth output is a third ratio, and wherein the first ratio is substantially similar to the second ratio and the third ratio, wherein the input of the first balanced optical power splitter is the input of the first power splitting device, and wherein the first output of the first balanced optical power splitter is the third output and the second output of the first balanced optical power splitter is the sixth output.

12. The system of claim 10, wherein the first balanced optical power splitter is configured to receive a range of wavelengths at the input, and wherein, for the range of wavelengths received at the input of the first balanced optical power splitter, the power output of the first output of the first balanced optical power splitter is balanced with the power output of the second output of the first balanced optical power splitter.

13. The system of claim 10, wherein
the first balanced optical power splitter is disposed at a central region of the semiconductor substrate, and
the semiconductor substrate further comprises a second balanced optical power splitter disposed at an edge region of the semiconductor substrate, the second balanced optical power splitter comprising an input, a first output, and a second output, wherein the power output of the first output of the second balanced optical power splitter is balanced with the power output of the second output of the second balanced optical power splitter.

14. The system of claim 10, wherein the semiconductor substrate further comprises a second device under test comprising a second input and a second test output, the second input coupled to the second output of the first balanced optical power splitter, wherein the processor is further configured to process the second test output.

15. The system of claim 10, wherein the semiconductor substrate is a silicon wafer.

16. A method of operating a balanced optical power splitter comprising:
providing an optical input signal; and
splitting the optical input signal into a first split optical signal and a second split optical signal, wherein the signal power of the first split optical signal is substantially different from the signal power of the second split optical signal;
splitting the first split optical signal to generate a first optical output signal comprising a first signal power; and
splitting the second split optical signal to generate a second optical output signal comprising a second signal power, wherein the first signal power is substantially similar to the second signal power.

17. The method of claim 16, wherein the optical input signal comprises a wavelength within a range of wavelengths, and wherein the first signal power is substantially similar to the second signal power for all wavelengths in the range of wavelengths.

18. The method of claim 17, wherein the range of wavelengths is between 1290 nm and 1330 nm.

19. The method of claim 16, wherein an absolute value of a deviation between the first signal power and the second signal power is less than a predetermined threshold, and wherein the deviation is a difference between a ratio of the first signal power to the second signal power and one.

20. The method of claim 19, wherein an absolute value of a deviation between the first split optical signal and the second split optical signal is greater than the predetermined threshold, and wherein the deviation is a difference between a ratio of the signal power of the first split optical signal to the signal power of the second split optical signal and one.
